(19) United States
(12) Patent Application Publication
(10) Pub. No.: US 2025/0226680 A1
(43) Pub. Date: Jul. 10, 2025

(54) METHOD AND APPARATUS WITH BATTERY CHARGING PATH GENERATION

(71) Applicant: Samsung Electronics Co., Ltd., Suwon-si (KR)

(72) Inventors: Ju Wan LIM, Suwon-si (KR); Jinho KIM, Suwon-si (KR); Duk Jin OH, Suwon-si (KR); Daeryong JUNG, Suwon-si (KR)

(73) Assignee: Samsung Electronics Co., Ltd., Suwon-si (KR)

(21) Appl. No.: 18/949,412

(22) Filed: Nov. 15, 2024

(30) Foreign Application Priority Data
Jan. 9, 2024 (KR) 10-2024-0003453

(51) Int. Cl. H02J 7/00; G01R 31/367; G01R 31/392

(52) U.S. Cl. CPC H02J 7/005; G01R 31/367; G01R 31/392; H02J 7/00716; H02J 7/007182

(57) ABSTRACT

A method including determining a first target charging time based on a first state of health (SOH) of a battery, generating simulation data for preset charging currents based on a battery model of the battery, generating an initial look-up table (LUT) for the preset charging currents and preset battery voltage limits based on the simulation data, the initial LUT representing initial charging limit conditions of the battery for intervals respectively corresponding to the charging currents, generating modified LUTs by adjusting one or more of the initial charging limit conditions of the initial LUT, responsive to the initial LUT failing to satisfy a first condition related to the first target charging time, determining a first final LUT based on a final LUT, responsive to the final LUT satisfying the first condition related to the first target charging time, and generating a first charging path for the battery based on the first final LUT.

### CROSS-REFERENCE TO RELATED APPLICATIONS

This application claims the benefit under 35 USC § 119(a) of Korean Patent Application No. 10-2024-0003453, filed on Jan. 9, 2024, in the Korean Intellectual Property Office, the entire disclosure of which is incorporated herein by reference for all purposes.

### BACKGROUND

### 1. Field

The following description relates to a method and apparatus with battery charging path generation.

### 2. Description of Related Art

Batteries are typically charged using various methods. For example, a constant current-constant voltage charging method charges a battery with constant currents, and charges the battery at a constant voltage when a voltage of the battery reaches a preset level. A varying current decay charging method charges a battery with a high current (i.e., amperage) at a low state of charge (SOC), and then gradually reduces the amount of current when the battery reaches a predetermined SOC from the charging. In addition, a multi-step charging method can charge a battery with constant currents, and a pulse charging method can charge a battery by repeatedly applying pulse currents in short time intervals.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In a general aspect, here is provided a method including determining a first target charging time based on a first state of health (SOH) of a battery, generating simulation data for preset charging currents based on a battery model indicating an internal state of the battery, generating an initial look-up table (LUT) for the preset charging currents and preset battery voltage limits based on the simulation data, the initial LUT representing initial charging limit conditions of the battery for intervals respectively corresponding to the charging currents, generating one or more modified LUTs by adjusting one or more of the initial charging limit conditions of the initial LUT, responsive to the initial LUT failing to satisfy a first condition related to the first target charging time, determining a first final LUT based on a final LUT of the one or more modified LUTs, responsive to the final LUT satisfying the first condition related to the first target charging time, and generating a first charging path for the battery based on the first final LUT.

The method may include determining the first SOH of the battery using a battery model.

The determining of the first target charging time based on the first SOH may include determining a first target charging time for a target charging interval, based on a first coefficient, a total reference charging time, the first SOH, and a reference sub-charging time for the target charging interval.

The method may include determining a second target charging time based on the first SOH, in response to the first final LUT failing to satisfy a second condition related to the second target charging time, generating an additional LUT based on the final LUT, in response to the additional LUT satisfying the second condition related to the second target charging time, determining a second final LUT based on the additional LUT, and generating a second charging path for the battery based on the second final LUT.

The second target charging time may be longer than the first target charging time.

The first charging path may be employed for charging the battery responsive to preset first circumstance and the second charging path may be employed for charging the battery responsive to a preset second circumstance.

The preset second circumstance may include a circumstance in which an electronic device charging the battery operates in a sleep mode.

The method may include obtaining one or more parameters indicating a state of the battery and updating the battery model based on the one or more parameters, the generating of the simulation data may include generating the simulation data for the preset charging currents based on the updated battery model.

The generating of the initial LUT may include determining, to be a first initial charging limit condition for a first interval, a first anode potential at a first point in time at which a first charging current of the preset charging currents reaches a first battery voltage limit of the preset battery voltage limits, determining, to be a second initial charging limit condition for a second interval, a second anode potential at a second point in time at which a second charging current of the preset charging currents reaches a second battery voltage limit of the preset battery voltage limits, and generating the initial LUT based on the first initial charging limit condition and the second initial charging limit condition.

The determining of whether the initial LUT satisfies the first condition may include generating a first charging result for the first interval and a second charging result for the second interval, generating a charging result for the initial LUT based on the first charging result and the second charging result, and determining whether the charging result satisfies the first condition.

The method may include generating the final LUT, the generating including generating a plurality of candidate LUTs by adjusting each of the initial charging limit conditions of the initial LUT within a preset range, calculating efficiencies for the plurality of candidate LUTs, determining a target stage showing a highest efficiency from among the intervals of the initial LUT based on the efficiencies, and generating the final LUT by adjusting a value of a target initial charging limit condition of intervals of the initial LUT.

The calculating of the efficiencies for the plurality of candidate LUTs may include calculating a first charging time and a first aging rate of a first candidate LUT and calculating a first efficiency for the first candidate LUT based on the first charging time and the first aging rate.

The calculating of the first charging time and the first aging rate of the first candidate LUT may include calculating a first sub-charging time and a first sub-aging rate for a first interval of the first candidate LUT, calculating a second sub-charging time and a second sub-aging rate for a second interval of the first candidate LUT, and calculating the first charging time based on the first sub-charging time and the second sub-charging time and calculating the first aging rate based on the first sub-aging rate and the second sub-aging rate.

The determining of the first final LUT may include calculating a first difference between a charging time of the final LUT and the first target charging time, calculating a second difference between a charging time of an LUT previous to the final LUT of the one or more modified LUTs and the first target charging time, and determining an LUT from among the one or more modified LUTs having a smaller one of the first difference and the second difference to be the first final LUT.

The battery may be provided in a mobile terminal or a vehicle.

In a general aspect, here is provided an electronic device which includes processors configured to execute instructions and a memory storing the instructions, an execution of the instructions configures the processors to determine a first target charging time based on a first state of health (SOH) of a battery, generate simulation data for preset charging currents based on a battery model indicating an internal state of the battery, generate an initial look-up table (LUT) for the charging currents and preset battery voltage limits based on the simulation data, the initial LUT representing initial charging limit conditions of the battery for intervals corresponding to the charging currents, generate a modified LUT by adjusting one or more of the initial charging limit conditions of the initial LUT, in response to the initial LUT failing to satisfy a first condition related to the first target charging time, determine a first final LUT based on the modified LUT, in response to the modified LUT satisfying the first condition related to the first target charging time, and generate a first charging path for the battery based on the first final LUT.

In a general aspect, here is provided a method of generating a charging path for a battery including determining a first state of health (SOH) of a battery, determining a first voltage limit for a first charging current based on the first SOH, determining a second voltage limit for a second charging current based on the first SOH, and generating a charging path for the battery based on the first voltage limit and the second voltage limit.

The determining of the first SOH of the battery may include determining a first internal resistance of the battery and determining the first SOH based on the first internal resistance.

The charging path for the battery further may include determining a first target charging time based on the first SOH of the battery; and determining a second target charging time based on the first SOH, wherein the second target charging time is longer than the first target charging time.

The generating of the charging path for the battery may include generating a first final LUT by iteratively adjusting one or more of initial charging limit conditions until one or more LUTs satisfy a first condition related to a first target charging time based on the first SOH of the battery and the generating of the first charging path for the battery may be based on the first final LUT.

### BRIEF DESCRIPTION OF THE DRAWINGS

FIG. 1 illustrates an example battery system according to one or more embodiments.

FIG. 2 illustrates an example configuration of an electronic device according to one or more embodiments.

FIG. 3 illustrates an example method of generating a charging path for a battery according to one or more embodiments.

FIG. 4 illustrates an example voltage of a battery with respect to a capacity of the battery according to a degree of aging of the battery according to one or more embodiments.

FIG. 5 illustrates examples of simulation data for charging currents according to one or more embodiments.

FIG. 6 illustrates an example method of generating an initial look-up table (LUT) according to one or more embodiments.

FIG. 7 illustrates an example method of determining whether an initial LUT satisfies a preset condition according to one or more embodiments.

FIG. 8 illustrates an example initial LUT according to one or more embodiments.

FIG. 9 illustrates an example method of generating a modified LUT based on an initial LUT according to one or more embodiments.

FIG. 10 illustrates an example method of calculating an efficiency for a candidate LUT for an initial LUT according to one or more embodiments.

FIG. 11 illustrates an example method of calculating an aging rate of a candidate LUT according to one or more embodiments.

FIG. 12 illustrates an example method of generating a re-modified LUT based on a modified LUT according to one or more embodiments.

FIG. 13 illustrates an example method of determining a final LUT from between a modified LUT and a LUT previous to the modified LUT according to one or more embodiments.

FIG. 14 illustrates an example initial LUT and a plurality of LUTs for generating a first charging path according to one or more embodiments.

FIG. 15 illustrates example charging paths determined for preset target charging times with respect to a voltage and an anode potential of a battery according to one or more embodiments.

FIG. 16 illustrates example charging paths determined for preset target charging times with respect to charging currents and a side reaction current according to one or more embodiments.

FIG. 17A illustrates an example change in the total charging time according to a change in a state of health (SOH) for each of first coefficients that are different from each other according to one or more embodiments.

FIG. 17B illustrates an example life improvement effect of a battery for each of first coefficients that are different from each other according to one or more embodiments.

FIG. 18 illustrates an example method of determining a second target charging time according to one or more embodiments.

FIG. 19 illustrates an example initial LUT and a plurality of LUTs for generating a second charging path according to one or more embodiments.

FIG. 20 illustrates an example method of generating a charging path for a battery based on a first voltage limit of a first charging current determined based on a first SOH of the battery and a second voltage limit of a second charging current according to one or more embodiments.

FIG. 21 illustrates an example vehicle according to one or more embodiments.

FIG. 22 illustrates an example mobile terminal according to one or more embodiments.

FIG. 23 illustrates an example electronic device according to one or more embodiments.

Throughout the drawings and the detailed description, unless otherwise described or provided, the same or like drawing reference numerals may be understood to refer to the same, or like, elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences within and/or of operations described herein are merely examples, and are not limited to those set forth herein, but may be changed as will be apparent after an understanding of the disclosure of this application, except for sequences within and/or of operations necessarily occurring in a certain order. As another example, the sequences of and/or within operations may be performed in parallel, except for at least a portion of sequences of and/or within operations necessarily occurring in an order, e.g., a certain order. Also, descriptions of features that are known after an understanding of the disclosure of this application may be omitted for increased clarity and conciseness.

The features described herein may be embodied in different forms, and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

Throughout the specification, when a component or element is described as being “on”, “connected to,” “coupled to,” or “joined to” another component, element, or layer it may be directly (e.g., in contact with the other component or element) “on”, “connected to,” “coupled to,” or “joined to” the other component, element, or layer or there may reasonably be one or more other components, elements, layers intervening therebetween. When a component or element is described as being “directly on”, “directly connected to,” “directly coupled to,” or “directly joined” to another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

The terminology used herein is for describing various examples only and is not to be used to limit the disclosure. The articles “a,” “an,” and “the” are intended to include the plural forms as well, unless the context clearly indicates otherwise. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof, or the alternate presence of an alternative stated features, numbers, operations, members, elements, and/or combinations thereof. Additionally, while one embodiment may set forth such terms “comprise” or “comprises,” “include” or “includes,” and “have” or “has” specify the presence of stated features, numbers, operations, members, elements, and/or combinations thereof, other embodiments may exist where one or more of the stated features, numbers, operations, members, elements, and/or combinations thereof are not present.

Due to manufacturing techniques and/or tolerances, variations of the shapes shown in the drawings may occur. Thus, the examples described herein are not limited to the specific shapes shown in the drawings, but include changes in shape that occur during manufacturing.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

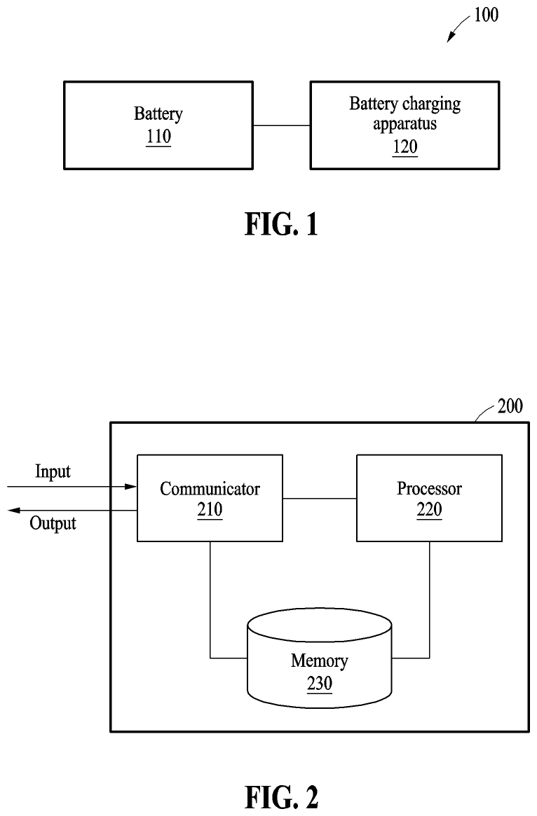

FIG. 1 illustrates an example battery system according to one or more embodiments.

Referring to FIG. 1, in a non-limiting example, battery system 100 may include a battery 110 and battery charging apparatus 120. The battery 110 may be one or more battery cells, battery modules, or battery packs. The battery 110 may include a capacitor, a secondary battery, or a lithium-ion battery for storing power as a result of charging. A device employing the battery 110 may receive power from the battery 110.

The battery charging apparatus 120 may charge the battery 110 using a battery model. In an example, the battery charging apparatus 120 may fast charge the battery 110 in a multi-step charging manner that minimizes aging that occurs from or results from being charged, such as in a fast charging scenario. The battery charging apparatus may use an estimate of the internal state of the battery based on the battery model. Here, the battery model may be an electrochemical model to which aging parameters of the battery 110 are applied and by using the aging parameters and/or other parameters, the battery model may estimate state information of the battery 110 by modeling internal physical phenomena such as potential and ion concentration distribution of the battery 110. In addition, the internal state of the battery 110 may include any one or any combination of a cathode lithium ion concentration distribution, an anode lithium ion concentration distribution, an electrolyte lithium ion concentration distribution, a cathode potential, and an anode potential of the battery 110. In an example, the aging parameters may include any one or any combination of an electrode balance shift, a capacity for cathode active material, and an anode surface resistance of the battery 110. However, examples are not limited thereto.

In an example, the battery charging apparatus 120 may divide the charging process into several charging stages (or steps) and charge the battery 110 with a charging current corresponding to each charging stage. For each of the charging stages, a charging limit condition for limiting charging of the battery 110 may be set which may from which the battery 110 may be charged by a target charge capacity during a target charging time while preventing aging of the battery 110.

In an example, the charging limit condition may include internal state conditions of the battery 110 for the respective charging stages. The internal state conditions may be defined by the electrochemical model based on at least one internal state that affects the aging of the battery 110. The internal state conditions may include any one or any combination of an anode overpotential condition, a cathode overpotential condition, an anode surface lithium ion concentration condition, a cathode surface lithium ion concentration condition, a cell voltage condition, and a state of charge (SOC) condition for the battery 110.

Since the battery 110 may be aged (i.e., experience a decrease in battery life, charge capacity, and/or ability to recharge) when one of the internal state conditions is reached as the battery 110 is charged, the battery charging apparatus 120 may control the charging of the battery 110 using the internal state conditions. Aging conditions are conditions that cause aging when an internal state of the battery 110 is reached. In an example, if it is determined that the battery 110 is aged when the anode overpotential of the battery 110 falls below 0.005 volts (V), the anode overpotential condition may be set based on 0.005 V. Here, the anode overpotential of 0.005 V may be an aging condition that causes aging when the anode overpotential of the battery 110 is reached. However, the internal state conditions are not limited to the examples above, and various expressions quantifying the internal states that affect the aging of the battery 110 may be employed.

Overpotential is a voltage drop caused by departing from the equilibrium potential associated with an intercalation/deintercalation reaction at each electrode of the battery 110. The lithium ion concentration described above is a concentration of lithium ions when the material in an active material of each electrode of the battery 110 is lithium ions. Materials other than lithium ions may be employed as the material in the active material.

A state of charge (SOC) is a parameter that indicates a charging state of the battery 110. The SOC indicates an amount of energy stored in the battery 110, and the amount may be expressed in percent (%), for example, indicated as 0% to 100%. For example, 0% may indicate a fully discharged state, and 100% may indicate a fully charged state. Such a metric may be variously modified in varied examples, for example, defined depending on a design intention or an aspect of such examples. The SOC may be estimated or measured using various schemes.

The battery 110 may include two electrodes (cathode and anode) for intercalation/deintercalation of lithium ions, an electrolyte that is a medium through which lithium ions may move, a separator that physically separates the cathode and the anode to prevent direct flow of electrons but which allows ions to pass therethrough, and a collector that collects electrons generated by an electrochemical reaction and/or supplies electrons required for an electrochemical reaction. The cathode may include a cathode active material, and the anode may include an anode active material. For example, lithium cobalt oxide (LiCoO2) may be used as the cathode active material, and graphite (C6) may be used as the anode active material. Lithium ions move from the cathode to the anode while the battery 110 is charged, and lithium ions move from the anode to the cathode while the battery 110 is discharged. Thus, the concentration of lithium ions in the cathode active material and the concentration of lithium ions in the anode active material change in response to charging and discharging.

The electrochemical model may be employed in various manners to express the internal state of the battery 110. In an example, a single particle model (SPM) and various application models may be employed for the electrochemical model, and parameters that define the electrochemical model may be variously modified depending on a design intention. The internal state conditions may be derived from the electrochemical model of the battery 110, or the internal state conditions may be derived experimentally or empirically. That is, the techniques for defining the internal state conditions is not limited.

The charging limit condition may include maximum charging times for the respective charging stages. A maximum charging time may be a condition for a maximum time required to charge the battery 110 with a charging current of a corresponding charging stage.

The charging limit condition may include anode potential limits for the respective charging stages. The anode potential of the battery 110 may decrease as the battery 110 is charged, and the anode potential limit may refer to the minimum anode potential allowed in the corresponding charging stage.

As described above, the internal state conditions and/or the charging limit conditions for the respective charging stages are charging conditions that may be set to achieve two objectives of preventing aging of the battery 110 and charging the battery by a target charge capacity during a target charging time, and these charging conditions may be controlled based on the charging efficiency of the battery 110 as described in greater detail below.

In an example, the battery charging apparatus 120 may control a charging stage of the battery 110 which may be switched from a first charging stage to a second charging stage at a point in time when the internal state of the battery 110 reaches one of the internal state conditions or when the charging time of the battery 110 reaches a maximum charging time while the battery 110 is charged with a first charging current in the first charging stage. The processes of switching between charging states may be iteratively performed until a last charging stage is reached.

Repeated use of the battery 110 may speed aging, and the aging rate of the battery 110 may vary depending on the usage history of the battery 110. If the battery 110 is charged without consideration of the aging rate, it may be impossible to avoid aging conditions from occurring during fast charging, which may lead to rapid aging and result in a reduction in the battery life. Accordingly, the battery charging apparatus 120 needs to adaptively perform charging control for the battery 110 based on the aging rate, which will be described in detail below with reference to the drawings.

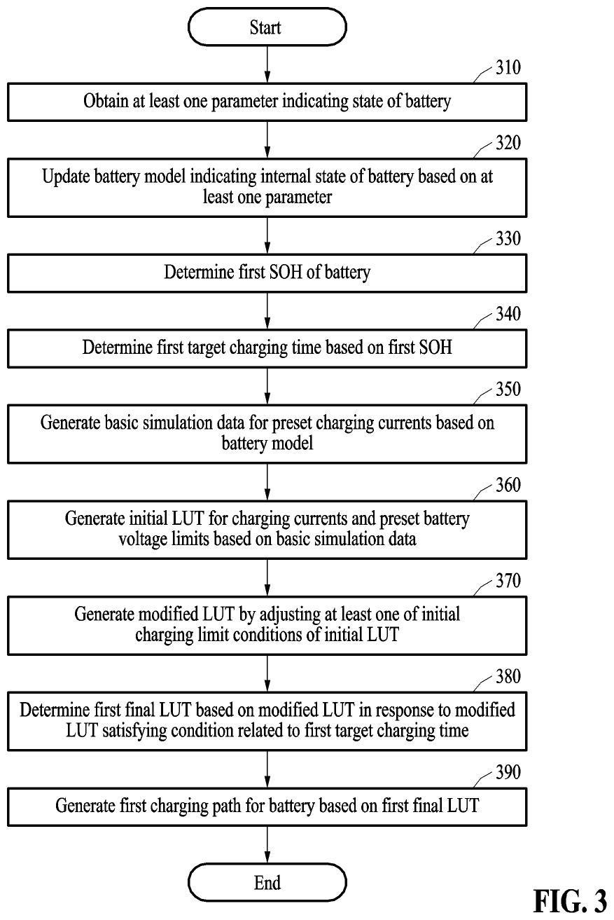

FIG. 2 illustrates an example electronic device according to one or more embodiments.

Referring to FIG. 2, in a non-limiting example, an electronic device 200 for controlling a battery may include a communicator 210, a processor 220, and a memory 230. In an example, the electronic device 200 may correspond to the battery charging apparatus 120 described above with reference to FIG. 1.

In an example, the electronic device 200 may be provided in a mobile communication terminal or a vehicle.

In an example, the communicator 210 may be connected to the processor 220 and the memory 230 and may transmit and receive data to and from the processor 220 and the memory 230. The communicator 210 may be connected to another external device and transmit and receive data to and from the external device. Hereinafter, transmitting and receiving “A” may refer to transmitting and receiving “information or data indicating A”.

The processor 220 may be configured to execute programs or applications to configure the processor 220 to control the electronic apparatus 100 to perform one or more or all operations and/or methods involving the reconstruction of images, and may include any one or a combination of two or more of, for example, a central processing unit (CPU), a graphic processing unit (GPU), a neural processing unit (NPU), a processor core, a multi-core processor, a multiprocessor, an application-specific integrated circuit (ASIC), and a field-programmable gate array (FPGA) and tensor processing units (TPUs), but is not limited to the above-described examples.

The memory 230 may include computer-readable instructions. The processor 220 may be configured to execute computer-readable instructions, such as those stored in the memory 230, and through execution of the computer-readable instructions, the processor 220 is configured to perform one or more, or any combination, of the operations and/or methods described herein. The memory 230 may be a volatile or nonvolatile memory. The memory 230 may include at least one volatile memory, non-volatile memory, random-access memory (RAM), flash memory, a hard disk drive, and an optical disc drive.

The memory 230 may store data received by the communicator 210 and data processed by the processor 220. For example, the memory 230 may store the program (or an application, or software). For example, the stored program may be a set of syntaxes that are coded and executable by the processor 220 to generate a charging path for a battery. As another example, the stored program may be a set of syntaxes that are coded and executable by the processor 220 to determine a charging limit condition of a battery.

The communicator 210 may be implemented as circuitry in the electronic device 200. In an example, the communicator 210 may include an internal bus and an external bus. In an example, the communicator 210 may be an element that connects the electronic device 200 to the external device. The communicator 210 may be an interface. The communicator 210 may receive data from the external device and transmit the data to the processor 220 and the memory 230.

The communicator 210 (e.g., an I/O interface) may include user interface may provide the capability of inputting and outputting information regarding electronic device 200 and other devices. The communicator 210 may include a network module for connecting to a network and a module for forming a data transfer channel with a mobile storage medium. In addition, the user interface may include one or more input/output devices, such as a display device, a mouse, a keyboard, a speaker, or a software module for controlling the input/output device.

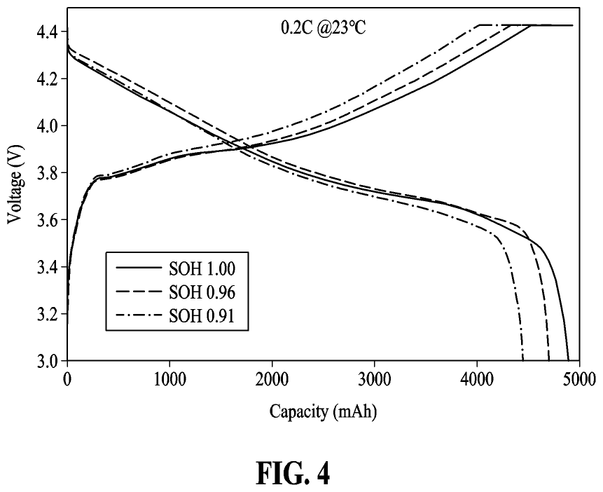

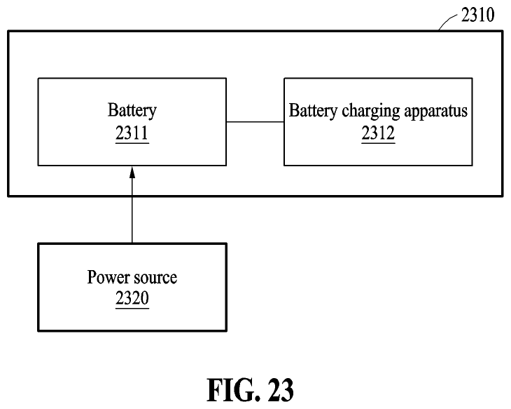

The communicator 210, the processor 220, and the memory 230 are described in greater detail below with reference to FIGS. 3 and 23.

FIG. 3 illustrates an example method of generating a charging path for a battery according to one or more embodiments.

In an example, operations 310 to 370 may be performed by the electronic device 200 as described above with reference to FIG. 2.

In operation 310, an electronic device may obtain at least one parameter indicating a state of a battery (e.g., the battery 110 of FIG. 1). In an example, the parameter indicating the state of the battery may be referred to as an aging parameter and the aging parameter may include an electrode balance shift, a capacity for cathode active material, and an anode surface resistance of the battery.

In operation 320, the electronic device may update a battery model indicating an internal state of the battery based on the obtained at least one parameter. In an example, the battery model may be an electrochemical model for estimating an internal state of the battery model based on various parameters. The battery model may estimate internal state information of the battery by modeling an internal physical phenomenon, such as a potential or an ion concentration distribution, of the battery.

The battery model may be employed in various manners to express the internal state of the battery. In an example, various application models may be adopted as the electrochemical model and parameters defining the electrochemical model may be variously modified depending on a design intention.

In an example, details concerning the internal state of the battery which may be estimated by the battery model may include any one or any combination of a cathode lithium ion concentration distribution, an anode lithium ion concentration distribution, an electrolyte lithium ion concentration distribution, a cathode potential, and an anode potential thereof.

As one or more parameters of the battery model are adjusted based on the aging parameter, the estimated internal state of the battery as estimated by the battery model may be changed.

In operation 330, the electronic device may determine a first state of health (SOH) of the battery. The SOH may be a parameter which quantitatively indicates a change in the life characteristic of a battery caused by aging, and may indicate a degree of degradation in the life or capacity of the battery. Various schemes may be employed to estimate or measure an SOH. In an example, an SOH value of a fresh battery may be determined to have a value of 1 and as a number of charge and discharge cycles of the battery increases, the SOH value of the battery may decrease below the initial value of 1.

In an example, the electronic device may determine the first SOH of the battery using at least one parameter indicating the state of the battery or a battery model. In an example, the electronic device may calculate an internal resistance of the battery and may determine the first SOH of the battery based on the calculated internal resistance. However, the method of determining the first SOH of the battery is not limited to the examples described above.

In operation 340, the electronic device may determine a first target charging time based on the first SOH. In an example, when the battery is completely charged through a determined charging path, the first target charging time may be related to a condition of the total time spent for charging the battery with respect to an interval that is set to be a fast charging interval in advance. Generally, as the charging time increases, an aging rate of the battery caused by charging may decrease (i.e., the slower the charging interval, the slower the aging rate of the battery).

In an example, the electronic device may determine the first target charging time for a target charging interval based on a first coefficient, a total reference charging time, the first SOH, and a reference sub-charging time with respect to the target charging interval. In an example, the target charging interval may be an entirety of a fast charging interval.

In an example, the first target charging time may be calculated based on Equation 1 shown below.

$${T}_{ch \_ target} = {T}_{ch \_ target \_ 0} - {α}_{1} \times {T}_{ch \_ full \_ 0} \times ( 1 - SOH ) \qquad Equation 1$$

In Equation 1, T_{ch_target} may be a first target charging time for a target charging interval, T_{ch_target_0} may be a reference sub-charging time for the target charging interval, α₁ may be a first coefficient, T_{ch_full_0} may be a total reference charging time, and SOH may be a first SOH. In an example, the reference sub-charging time for the target charging interval may be a preset charging time for the target charging interval when the battery is not used. The total reference charging time may be a charging time for all SOC intervals (e.g., an SOC value of 0 to 1).

In equation 1, α₁ may be a proportional factor and may be determined between 0 and −6. In an example, a value of α₁ may be determined by a user of the electronic device. In an example, α₁ may indicate ΔT_{ch} %/ΔSOH %. ΔT_{ch} % may be a change rate of the total charging time calculated for the first SOH compared to a total charging time calculated for an SOH before the first SOH is determined. In equation 1, ΔSOH % may be a change rate of the first SOH compared to a previous SOH.

In an example, the electronic device may suggest a range of an appropriate value of α₁ to the user and the user may select the value of α₁ from the proposed range. The suggested range of the value of α₁ may be between −0.2 and −2.

In an example, the electronic device may determine a first total charging time based on the total reference charging time, the first target charging time, and the reference sub-charging time for the target charging interval.

In an example, the first total charging time may be T_{ch_full} calculated based on Equation 2 shown below.

$${T}_{ch \_ full} = {T}_{ch \_ full \_ 0} + ( {T}_{ch \_ target} - {T}_{ch \_ target \_ 0} ) \qquad Equation 2$$

In an example, when a total reference charging time of a new battery is 75 minutes and a charging time (in other words, a reference sub-charging time) from an SOC 0 to an SOC 0.71, which is a target charging interval, is 30 minutes, T_{ch_target_0} may be 30 and T_{ch_full_0} may be 75. When α₁ is −1 and the first SOH is 0.9, T_{ch_target}, which is a first target charging time for the target charging interval, may be calculated to be 37.5 minutes and T_{ch_full}, which is a first total charging time, may be calculated to be 82.5 minutes.

In operation 350, the electronic device may generate simulation data for preset charging currents based on the battery model. In an example, the preset charging currents may include 7.92 amperes (A), 7.57 A, 7.12 A, 6.67 A, 6.23 A, 5.79 A, 5.34 A, 4.89 A, and 4.45 A. However, the preset charging currents are not limited to the examples described above.

In an example, the electronic device may generate simulation data for a partial interval that is preset to be a fast charging interval of a total charge capacity of the battery. In an example, the fast charging interval of the total charge capacity may include an SOC ranging from 0.04 to 0.71. A maximum charging time and battery voltage limits for the charging currents may be preset to generate the simulation data.

In an example, first simulation data indicating an internal state of the battery may be generated by charging the battery with a first charging current in the fast charging interval. In an example, if the fast charging interval includes an SOC ranging from 0.04 to 0.71, the generation of the first simulation data may be terminated in response to the SOC reaching 0.71 or a battery voltage reaching a first battery voltage limit set for the first charging current. If the number of preset charging currents is n, n pieces of simulation data may be generated.

A side reaction current may be calculated based on simulation data. For example, the side reaction current may be calculated based on the Butler-Volmer equation.

The Butler-Volmer equation is a calculation formula that obtains an amount of lithium ions consumed by an anode side reaction (that is, an amount of anode side reaction) and may be expressed by Equation 3 below.

$${j}_{s i d e}^{L i} = {a}_{s} {i}_{0 , s i d e} [ exp ( \frac{{α}_{a , side} {n}_{side} F}{R T} {η}_{side} ) - exp ( - \frac{{α}_{c , side} {n}_{side} F}{R T} {η}_{side} ] ) \qquad Equation 3$$

In Equation 3, j_{side}^{Li} may denote an electrode current density related to lithium ion consumption by an anode side reaction. An amount of lithium ions consumed by the anode side reaction may be obtained by integrating j_{side}^{Li} with respect to time. In addition, as may denote an active surface area of an anode and i_{0,side} may denote an exchange current density for the anode side reaction. In an example, α_{a,side} may denote an anodic charge transfer coefficient, α_{c,side} may denote a cathodic charge transfer coefficient, and for example, the anodic charge transfer coefficient and the cathodic charge transfer coefficient may each have a value of 0.5. In addition, n_{side} may denote a number of molecules involved in the anode side reaction, F may denote a Faraday constant, R may denote an ideal gas constant, and T may denote a temperature. In addition, η_{side} may denote an anode overpotential for a side reaction and may be expressed by Equation 4 shown below.

$${η}_{side} = {ϕ}_{s} - {ϕ}_{e} - {U}_{eq , side} - \frac{{R}_{SEI , total}}{{a}_{s , side}} {j}_{t o t a l}^{L i} \qquad Equation 4$$

In Equation 4, ϕₛ may denote a potential of a solid and ϕₑ may denote a potential of an electrolyte. In addition, U_{eq,side} may denote an equilibrium potential for the side reaction and may be set to 0.4 volts (V), for example. In addition, R_{SEI,total} may denote a resistance by an SEI layer formed on an anode surface, a_{s,side} may denote an active surface area of the anode, and jₜₒₜₐₗ^{Li} may denote an electrode current density related to all lithium ions.

The exchange current density i_{0,side} described above may be expressed by Equation 5 below.

$${i}_{0 , s i d e} = {k}_{side} \sqrt{{c}_{s , surf} {c}_{EC , Rs}} \qquad Equation 5$$

In Equation 5, k_{side} may denote a kinetic rate constant for the side reaction, c_{s,surf} may denote a lithium ion concentration on an electrode (for example, anode) surface, and c_{EC,Rs} may denote an electrolyte concentration on the electrode surface.

In operation 360, the electronic device may generate an initial look-up table (LUT) for the charging currents and the preset battery voltage limits based on the simulation data.

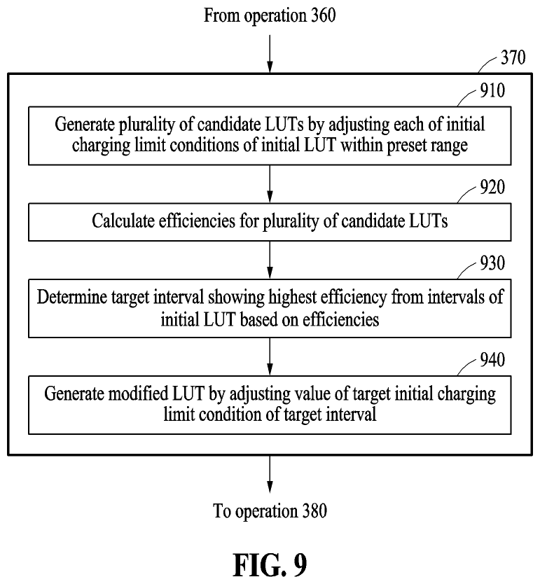

In an example, the preset charging currents may include 7.92 A, 7.57 A, 7.12 A, 6.67 A, 6.23 A, 5.79 A, 5.34 A, 4.89 A, and 4.45 A. The initial LUT for the preset charging currents is shown in FIG. 8.

In an example, the preset charging currents may be used to charge the battery in the fast charging interval, and the fast charging interval may be divided into intervals in which the charging currents are used. In an example, an interval in which 7.92 A is used may be defined as a first interval, an interval in which 7.57 A is used may be defined as a second interval, an interval in which 7.12 A is used may be defined as a third interval, an interval in which 6.67 A is used may be defined as a fourth interval, an interval in which 6.23 A is used may be defined as a fifth interval, an interval in which 5.79 A is used may be defined as a sixth interval, an interval in which 5.34 A is used may be defined as a seventh interval, an interval in which 4.89 A is used may be defined as an eighth interval, and an interval in which 4.45 A is used may be defined as a ninth interval.

That is, the first interval may correspond to a period from a start point of the fast charging interval to a point in time at which the battery voltage reaches 4.130 V while the battery is being charged with 7.92 A. The second interval may correspond to a period from an end point of the first interval to a point in time at which the battery voltage reaches 4.130 V while the battery is being charged with 7.57 A. The third interval may correspond to a period from an end point of the second interval to a point in time at which the battery voltage reaches 4.130 V while the battery is being charged with 7.12 A. The fourth interval may correspond to a period from an end point of the third interval to a point in time at which the battery voltage reaches 4.300 V while the battery is being charged with 6.67 A. The fifth interval may correspond to a period from an end point of the fourth interval to a point in time at which the battery voltage reaches 4.300 V while the battery is being charged with 6.23 A. The sixth interval may correspond to a period from an end point of the fifth interval to a point in time at which the battery voltage reaches 4.300 V while the battery is being charged with 5.79 A. The seventh interval may correspond to a period from an end point of the sixth interval to a point in time at which the battery voltage reaches 4.300 V while the battery is being charged with 5.34 A. The eighth interval may correspond to a period from an end point of the seventh interval to a point in time at which the battery voltage reaches 4.300 V while the battery is being charged with 4.89 A. The ninth interval may correspond to a period from an end point of the eighth interval to a point in time at which the battery voltage reaches 4.380 V while the battery is being charged with 4.45 A.

In an example, an initial LUT 810 of FIG. 8 may be generated to represent initial charging limit conditions 820 of the battery for the intervals corresponding to the charging currents. For example, the initial charging limit conditions 820 may be anode potentials of the battery. However, examples are not limited thereto.

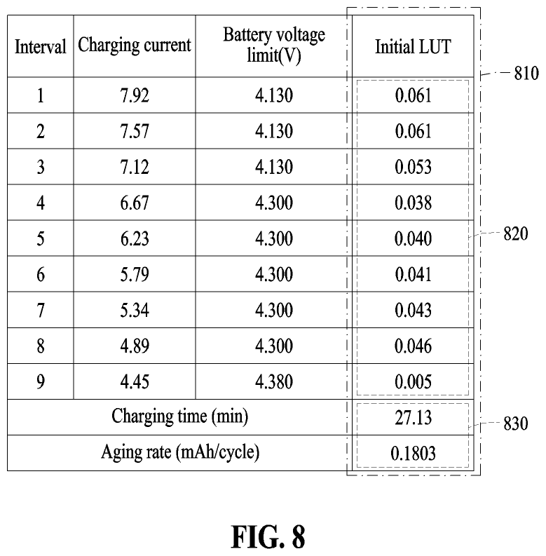

The initial LUT 810 may further include, as charging results 830, a charging time and an aging rate required when the battery is charged with a charging path according to the initial LUT 810. An example of calculating the charging time and the aging rate as the charging results 830 will be described in greater detail below with reference to FIG. 7.

In operation 370, the electronic device may generate a modified LUT by adjusting at least one of the initial charging limit conditions of the initial LUT.

In an example, the electronic device may determine whether a charging result according to the charging path of the initial LUT satisfies a preset condition, and may then generate a modified LUT by adjusting at least one of the initial charging limit conditions of the initial LUT, in response to the charging result failing to satisfy the preset condition. In an example, an initial charging limit condition may be an anode potential and the preset condition may be whether a total charging time for the fast charging interval elapses a preset time (e.g., the first target charging time).

In an example, an anode potential limit of the first interval (e.g., the interval in which the charging current of 7.92 A is used), among the intervals of the fast charging interval, may be adjusted from 0.061 V to 0.062 V. In this case, the initial LUT and the modified LUT may be referred to as a first LUT and a second LUT, respectively.

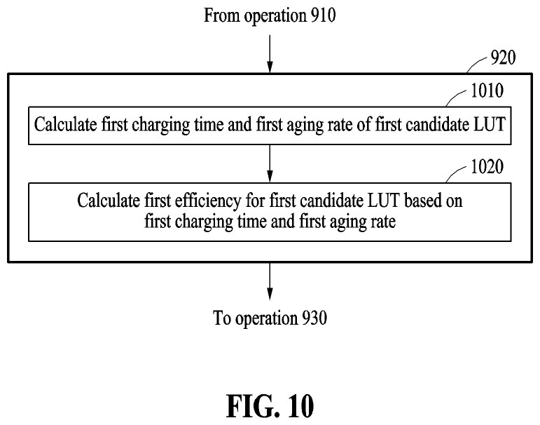

A charging limit condition for any one interval (i.e., target interval), among the intervals of the fast charging interval, may be adjusted, while the charging limit conditions of the other intervals may not be adjusted. In an example, in the initial LUT 810 of FIG. 8, only an anode potential limit for the first stage may be adjusted, and anode potential limits for the second to ninth stages may not be adjusted. Hereinafter, a detailed description of determining a target interval from a plurality of intervals is provided with reference to FIGS. 9 to 12.

In an example, for a modified LUT, a determination may be made as to whether a charging result according to a charging path of the modified LUT satisfies a preset condition and when the charging result does not satisfy the condition, a re-modified LUT may be generated by adjusting at least one of charging limit conditions of the modified LUT. In this case, the modified LUT and the re-modified LUT may be referred to as a second LUT and a third LUT, respectively.

Referring to FIG. 3, in operation 380, the electronic device may determine a first final LUT based on the modified LUT when the modified (or re-modified) LUT satisfies the preset condition. In an example, the preset condition may be whether the charging time for the fast charging stage using the charging path of the modified LUT exceeds a preset time (e.g., the first target charging time).

In an example, the electronic device may determine the modified LUT (e.g., an n-th LUT) or a previous LUT (e.g., an n−1-th LUT) of the modified LUT to be the first final LUT based on a preset policy.

In operation 390, the electronic device may generate a first charging path for the battery based on the first final LUT. The first charging path may be a path in which each interval of the fast charging interval is changed.

In an example, a condition for changing from the first interval to the second interval of the first charging path may be a charging limit condition for the first interval of the first final LUT. When the charging limit condition is an anode potential and an anode potential of the battery that is estimated while the battery is charged with a first current (e.g., 7.92 A) reaches an anode potential limit for a first interval of the first final LUT, the charging current may be changed from the first current to the second current (e.g., 7.57 A).

In an example, the battery and the electronic device may be included in a terminal and the terminal may charge the battery using the determined first charging path. For example, when a power source is connected to the terminal, the terminal may estimate a current internal state of the battery, may determine an interval of the first charging path corresponding to the estimated internal state, and may charge the battery using a current corresponding to the determined interval.

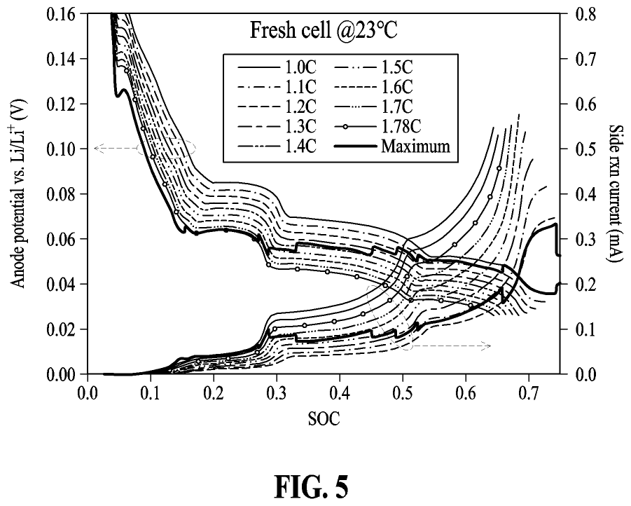

FIG. 4 illustrates an example voltage of a battery with respect to a capacity of the battery according to a degree of aging of the battery according to one or more embodiments.

Referring to FIG. 4, in a non-limiting example, a capacity of a battery may decrease as an SOH decreases. The graph of FIG. 4 illustrates that as the SOH is lowered, the voltage of the battery at the same capacity of the battery may be greater.

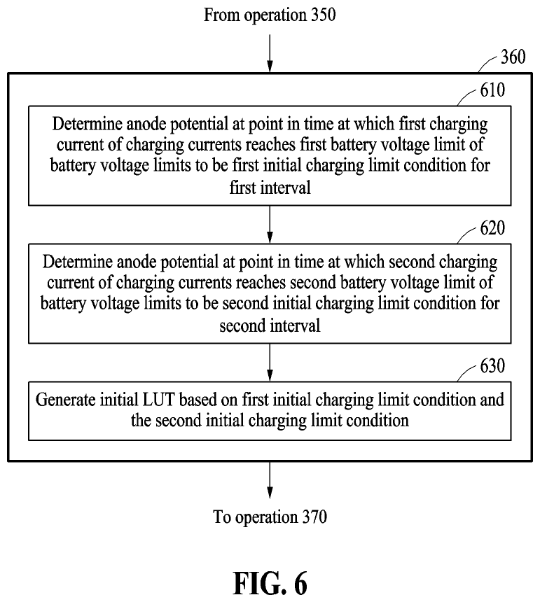

FIG. 5 illustrates examples of simulation data for charging currents according to one or more embodiments.

Referring to FIG. 5, in a non-limiting example, simulation data that may be generated by operation 350, as described above with reference to FIG. 3, are illustrated. In an example, 7.92 A, 7.57 A, 7.12 A, 6.67 A, 6.23 A, 5.79 A, 5.34 A, 4.89 A, and 4.45 A may correspond to 1.78 C, 1.7 C, 1.6 C, 1.5 C, 1.4 C, 1.3 C, 1.2 C, 1.1 C, and 1.0 C, respectively.

In addition, FIG. 5 also illustrates a side reaction current calculated based on the basic simulation data.

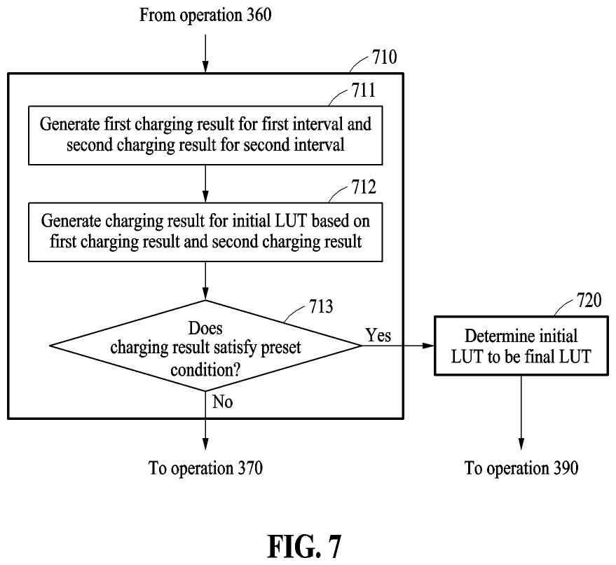

FIG. 6 illustrates an example method of generating an LUT according to one or more embodiments.

Referring to FIG. 6, in a non-limiting example, operation 360 as described above with reference to FIG. 3 may include operations 610 to 630. Operations 610 to 630 may be performed by an electronic device (e.g., the electronic device 200 of FIG. 2).

In operation 610, in an example, the electronic device may determine an anode potential at a point in time at which a first charging current of preset charging currents reaches a first battery voltage limit of battery voltage limits which may be a first initial charging limit condition for a first interval. Although it is described that the initial charging limit condition is an anode potential, examples are not limited thereto. For example, the initial charging limit condition may be at least one of estimated internal states of the battery.

In operation 620, the electronic device may determine an anode potential at a point in time at which a second charging current of the preset charging currents reaches a second battery voltage limit of the battery voltage limits which may be a second initial charging limit condition for a second interval.

In operation 630, the electronic device may generate an initial LUT based on the first initial charging limit condition and the second initial charging limit condition. For example, the initial LUT 810 of FIG. 8, as discussed in greater detail below, may be generated to include the initial charging limit conditions 820.

FIG. 7 illustrates an example method of determining whether an initial LUT satisfies a preset condition according to one or more embodiments.

Referring to FIG. 7, in a non-limiting example, the method of generating a charging path for a battery described above with reference to FIG. 3 may further include operations 710 and 720. Operations 710 and 720 may be performed by an electronic device (e.g., the electronic device 200 of FIG. 2).

In an example, operation 710 may include operations 711 to 713.

In operation 711, the electronic device may generate a first charging result for a first interval and a second charging result for a second interval. In an example, a charging result for a predetermined interval may be a partial charging time of the predetermined interval. In an example, the charging result for the predetermined interval may be an aging rate of the predetermined interval. The aging rate may correspond to an amount of anode side reaction.

In operation 712, the electronic device may generate a charging result for an initial LUT based on the first charging result and the second charging result. In an example, the charging result may be generated by accumulating the first charging result and the second charging result.

In operation 713, the electronic device may determine whether the charging result of the initial LUT satisfies a preset condition. In an example, a first target charging time (e.g., 30 minutes) may be set to be the preset condition and whether the charging result according to the initial LUT exceeds 30 minutes may be determined.

In response to the charging result of the initial LUT failing to satisfy the preset condition, operation 370 described above with reference to FIG. 3 may be performed. Conversely, in response to the charging result of the initial LUT satisfying the preset condition, operation 720 may be performed.

In operation 720, the electronic device may determine the initial LUT to be a final LUT.

In an example, the initial LUT may correspond to a charging path in which a charging time of the battery is minimized based on an aged state of the current battery. The charging path with the minimized charging time may be a charging path in which an aging rate is maximized. In other words, there may be tradeoffs in the relationship between the charging time and the aging rate. In an example, when the first target charging time is set to be short as the preset condition, the charging result of the initial LUT may immediately satisfy the preset condition. In this case, the initial LUT may be determined to be the final LUT.

In an example, after operation 720 is performed, operation 390 described above with reference to FIG. 3 may be performed.

FIG. 8 illustrates an example of an initial LUT according to one or more embodiments.

Referring to FIG. 8, in a non-limiting example, the initial LUT 810 may include initial charging limit conditions 820 and a charging result 830.

In an example, the initial charging limit conditions 820 may be anode potentials of the battery for respective intervals.

In an example, the charging results 830 may include a charging time and an aging rate according to the charging path of the initial LUT.

FIG. 9 illustrates an example method of generating a modified LUT based on an initial LUT according to one or more embodiments.

Referring to FIG. 9, in a non-limiting example, operation 370, as described above with reference to FIG. 3, may include operations 910 to 940. Operations 910 to 940 may be performed by an electronic device (e.g., the electronic device 200 of FIG. 2).

In operation 910, the electronic device may generate a plurality of candidate LUTs by adjusting each of the initial charging limit conditions of the initial LUT within a preset range.

In an example, the charging limit conditions may be anode potentials, the preset range may be 10 mV, and the value of adjustment may be 1 mV. In an example, if a first anode potential limit for a first interval is 0.061 V, ten candidate LUTs in which the first anode potential limit is adjusted to 0.062 V, 0.063 V, 0.064 V, 0.065 V, 0.066 V, 0.067 V, 0.068 V, 0.069 V, 0.070 V, and 0.071 V may be generated. Anode potential limits for intervals other than the first interval may not be adjusted. In an example, when there are nine intervals, there may be 9×10 candidate LUTs for the initial LUT.

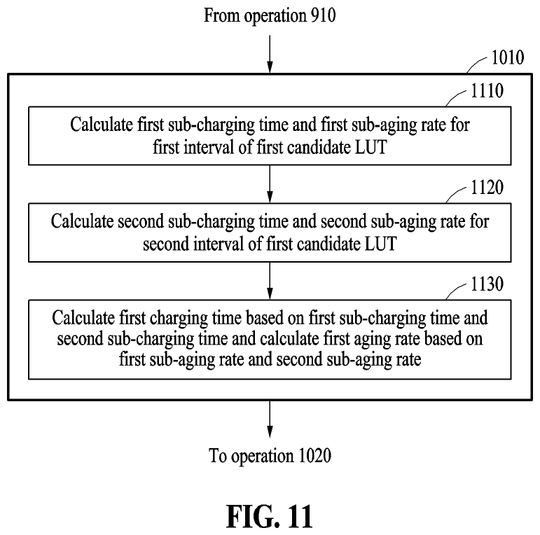

In operation 920, the electronic device may calculate efficiencies for the plurality of candidate LUTs. A detailed description of respectively calculating the efficiencies for the candidate LUTs is discussed in greater detail below with reference to FIG. 10.

In operation 930, the electronic device may determine a target interval showing a highest efficiency from the intervals of the initial LUT based on the calculated efficiencies. In an example, when a candidate LUT showing the highest efficiency among 90 candidate LUTs is an LUT in which an anode potential limit of the second interval is adjusted from 0.061 V to 0.068 V, the second interval may be determined to be the target interval.

In operation 940, the electronic device may generate a modified LUT by adjusting a value of a target initial charging limit condition of the target interval. In an example, the value of the target initial charge limit condition may be adjusted by a preset value (e.g., 1 mV). In this example, if the second interval is determined to be the target interval, the initial anode potential limit of the second interval may be adjusted from 0.061 V to 0.062 V.

FIG. 10 illustrates an example method of calculating an efficiency for a candidate LUT for an initial LUT according to one or more embodiments.

Referring to FIG. 10, in a non-limiting example, operation 920, as described above with reference to FIG. 9, may include operations 1010 and 1020. Operations 1010 and 1020 may be performed by an electronic device (e.g., the electronic device 200 of FIG. 2).

In operation 1010, the electronic device may calculate a first charging time and a first aging rate of a first candidate LUT of a plurality of candidate LUTs.

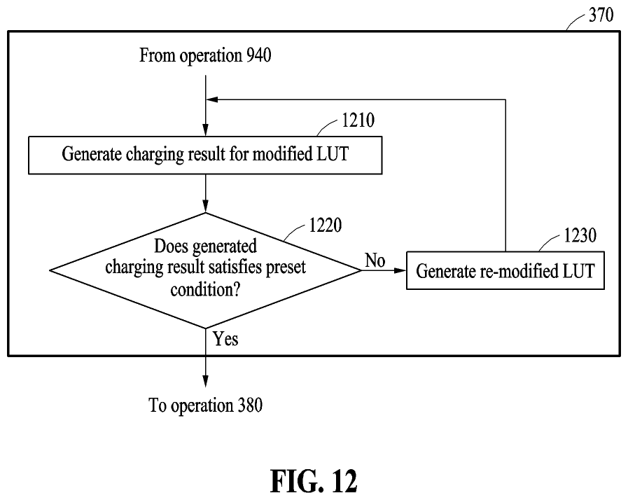

Another example of calculating the first charging time and the first aging rate of the first candidate LUT is described in greater detail below with reference to FIG. 11.

In operation 1020, the electronic device may calculate a first efficiency for the first candidate LUT based on a reference aging rate, a reference charging time, the first charging time, and the first aging rate. The reference aging rate and the reference charging time may be an aging rate and a charging time by charging limit conditions of the initial LUT. In an example, the first efficiency may be calculated by Equation 6 shown below.

$$First efficiency = \frac{Refe rence aging rate - First aging rate}{First charging time - r e f e rence charging time} \qquad Equation 6$$

While examples of calculating the efficiency for the candidate LUT for the initial LUT are described with reference to FIG. 10, other instances may similarly apply to, in an example, calculating the efficiency for a candidate LUT for a modified LUT (e.g., the second LUT). In this case, the reference aging rate and the reference charging time may correspond to an aging rate and a charging time by the charging limit conditions of the modified LUT.

FIG. 11 illustrates an example method of calculating an aging rate of a candidate LUT according to one or more embodiments.

Referring to FIG. 11, in a non-limiting example, operation 1010, as described above with reference to FIG. 10, may include operations 1110 to 1130. Operations 1110 to 1130 may be performed by an electronic device (e.g., the electronic device 200 of FIG. 2).

In operation 1110, the electronic device may calculate a first sub-charging time and a first sub-aging rate for a first interval of a first candidate LUT. In an example, the first sub-charging time may be a time from a start point of the first interval to a start point of a second interval. In an example, the first sub-aging rate may be calculated based on a side reaction current generated in the first interval.

In operation 1120, the electronic device may calculate a second sub-charging time and a second sub-aging rate for the second interval of the first candidate LUT. In an example, the second sub-charging time may be a time from the start point of the second interval to a start point of a third interval. In an example, the second sub-aging rate may be calculated based on a side reaction current generated in the second interval.

In operation 1130, the electronic device may calculate the first charging time of the first candidate LUT based on the first sub-charging time and the second sub-charging time and may calculate the first aging rate of the first candidate LUT based on the first sub-aging rate and the second sub-aging rate.

In an example, the first charging time may be calculated by accumulating the first sub-charging time and the second sub-charging time. In an example, the first aging rate may be calculated by accumulating the first sub-aging rate and the second sub-aging rate.

The calculating the first charging time and the first aging rate of the first candidate LUT is described above in greater detail with reference to FIG. 11. However, the description may similarly apply to an example of calculating a charging time and an aging rate of each of the initial LUT and the modified LUT.

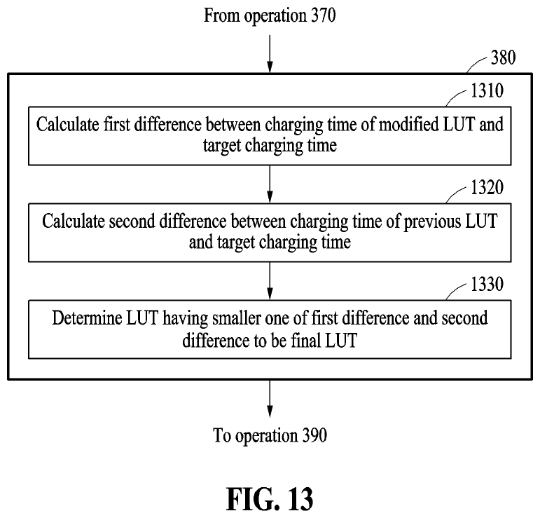

FIG. 12 illustrates an example method of generating a re-modified LUT based on a modified LUT according to one or more embodiments.

Referring to FIG. 12, in a non-limiting example, operation 370, as described above with reference to FIGS. 3 and 9, may further include operations 1210 to 1230. After operation 940 described with reference to FIG. 9 is performed, operation 1210 may be performed. Operations 1210 to 1230 may be performed by an electronic device (e.g., the electronic device 200 of FIG. 2).

In operation 1210, the electronic device may generate a charging result for a modified LUT.

In an example, the description of operation 1210 may instead be replaced with the descriptions of operations 711 and 712 as described above in greater detail with reference to FIG. 7.

In operation 1220, the electronic device may determine whether the charging result of the modified LUT satisfies a preset condition. In an example, a first target charging time (e.g., 30 minutes) may be set to be the preset condition and whether the charging result according to the modified LUT exceeds 30 minutes may be determined.

In an example, the description of operation 1220 may instead be replaced with the description of operation 713 as described in greater detail above with reference to FIG. 7.

In an example, in response to the charging result of the modified LUT satisfying the preset condition, operation 380, as described above with reference to FIG. 3, may be performed. Conversely, in response to the charging result of the modified LUT failing to satisfy the preset condition, operation 1230 may be performed.

In operation 1230, the electronic device may generate a re-modified LUT by adjusting at least one of the charging limit conditions of the modified LUT. In an example, the description of the example of generating the re-modified LUT may be replaced with the description of operations 910 to 940, as described in greater detail above with reference to FIG. 9.

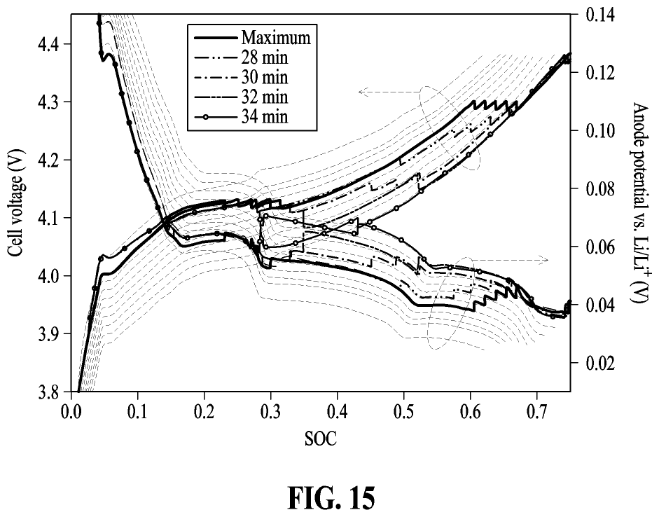

A detailed description of iteratively modified LUTs is provided in greater detail below with reference to FIG. 14.

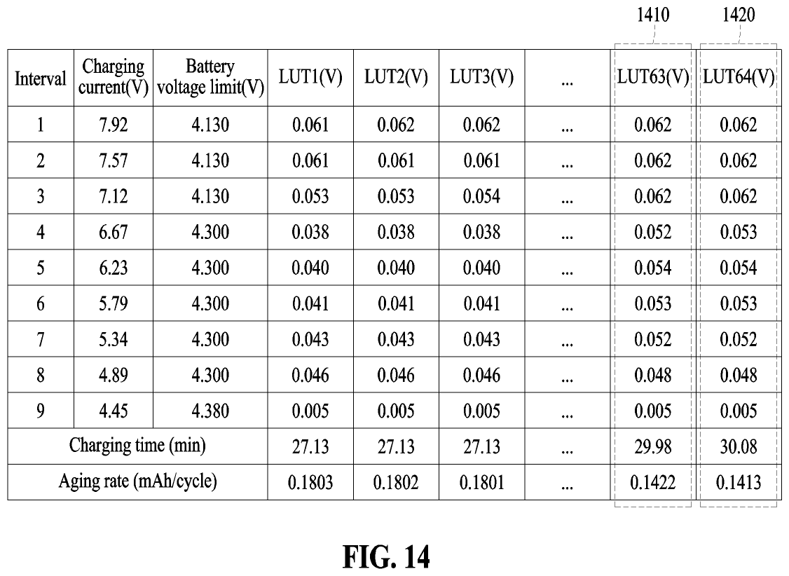

FIG. 13 illustrates an example method of determining a final LUT from between a modified LUT and a LUT previous to the modified LUT according to one or more embodiments.

Referring to FIG. 13, in a non-limiting example, operation 380, as described above with reference to FIG. 3, may include operations 1310 to 1330. Operations 1210 to 1230 may be performed by an electronic device (e.g., the electronic device 200 of FIG. 2).

In operation 1310, the electronic device may calculate a first difference between a charging time of a modified LUT and a target charging time (e.g., the first target charging time). In an example, when the charging time of the modified LUT is 30.08 minutes and the target charging time is 30 minutes, the first difference may be calculated to be 0.08 minutes.

In operation 1320, the electronic device may calculate a second difference between a charging time of a previous LUT of the modified LUT and the target charging time (e.g., the first target charging time). In an example, when the charging time of the previous LUT is 29.98 minutes and the target charging time is 30 minutes, the second difference may be calculated to be 0.02 minutes.

In operation 1330, the electronic device may determine an LUT having a smaller one of the first difference and the second difference to be a final LUT. In the above example, since the first difference is 0.08 minutes and the second difference is 0.02 minutes, the LUT previous to the modified LUT may be determined to be the final LUT.

FIG. 14 illustrates an example initial LUT and a plurality of LUTs according to one or more embodiments.

Referring to FIG. 14, in a non-limiting example, when a first target charging time is set to be 30 minutes, it may be determined that a result of LUT64 1420 satisfies a preset condition. In an example, one of the plurality of LUTs may be determined to be a first final LUT according to a preset policy.

In an example, LUT64 1420 may be determined to be the first final LUT.

In an example, LUT63 1410, which is an LUT previous to LUT64 1420, may be determined to be the first final LUT.

In an example, since a difference for LUT64 1420 is calculated to be 0.08 minutes and a difference for LUT63 1410, which is the LUT previous to LUT64 1420, is calculated to be 0.02 minutes, LUT63 1410 may be determined to the first final LUT.

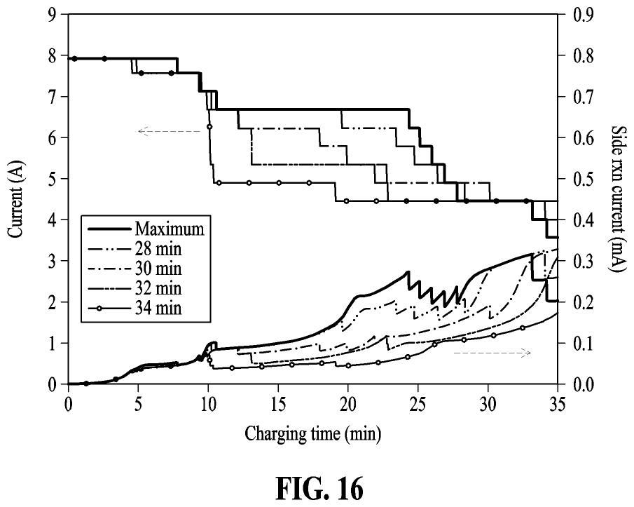

FIG. 15 illustrates example charging paths determined for preset target charging times with respect to a voltage and an anode potential of a battery according to one or more embodiments.

Referring to FIG. 15, in a non-limiting example, because an anode potential of the battery decreases as an SOC increases, a side reaction current that increases when the anode potential decreases may increase as the SOC increases.

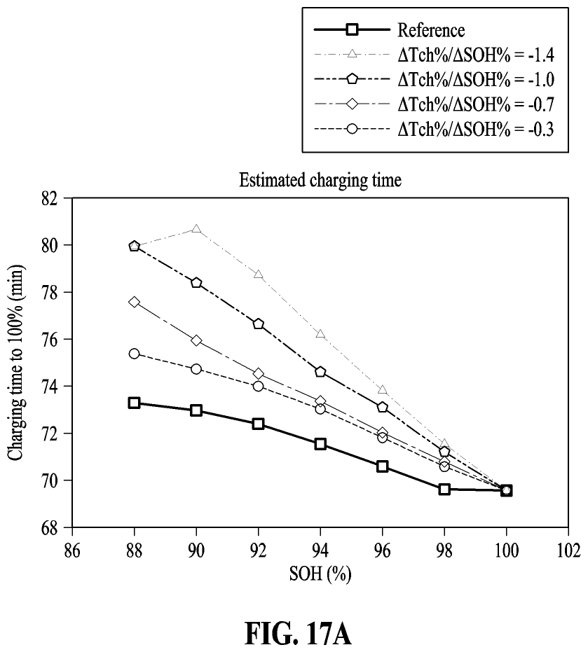

FIG. 16 illustrates example charging paths determined for preset target charging times with respect to charging currents and a side reaction current according to one or more embodiments.

Referring to FIG. 16, in a non-limiting example, a high charging current may be used relatively longer as a target charging time decreases. The longer the high charging current is used, the larger the side reaction current appears, which may result in an increase in the aging rate. Because there is a trade-off in the relationship between the charging time and the aging rate, a charging path for charging the battery most efficiently (or while minimizing the aging rate) within a predetermined charging time may be desired.

The charging path for charging the battery most efficiently within the predetermined charging time may be generated through operations 310 to 390, as described in greater described above.

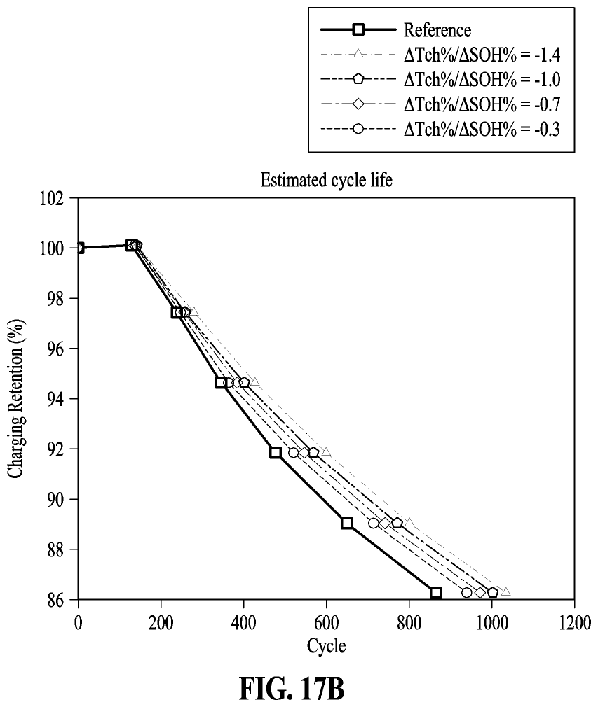

FIG. 17A illustrates an example change in the total charging time according to a change in a state of health (SOH) for each of first coefficients that are different from each other according to one or more embodiments.

Referring to FIG. 17A, in a non-limiting example, in a fast charging interval of the total charging intervals of the battery, a time required to fully charge the battery may increase as the first coefficient decreases. The same trend may be observed for a change in an SOH of the battery. A reference curve may correspond to a case in which the first coefficient is 0. In an example, when the first coefficient is −1.0 or −1.4, the first target charging time may increases as the battery is aged, and when the SOH of the battery finally reaches an end of life (EOL), the total charging time may increase by approximately 10% compared to a case in which the first coefficient is 0.

When the SOH is 0.88, the total charging time of a case in which the first coefficient is −1.0 and the total charging time of a case in which the first coefficient is −1.4 may be the same. This is because the battery is charged using currents that may only correspond to partial intervals of the charging intervals when the SOH is 0.88. In an example, when the SOH is 0.88, the battery may be charged using a current of 4.45 A corresponding to a ninth interval among first to ninth intervals. When the SOH is less than 0.88, even if the first coefficient is less than −1.0, a life improvement effect that is greater than that of a case in which the first coefficient is −1.0 may not occur.

FIG. 17B illustrates an example life improvement effect of a battery for each of first coefficients that are different from each other according to one or more embodiments.

Referring to FIG. 17B, in a non-limiting example, a capacity retention rate of a battery according to the number of charge and discharge cycles of the battery illustrates the life improvement effect described above for the examples of FIG. 17A. Compared to a retention rate of the reference in which the first coefficient is 0, retention rates when the first coefficients are −0.3, −0.7, −1.0, and −1.4 may be expected to be improved by approximately 10%, 14%, 17%, and 22%, respectively.

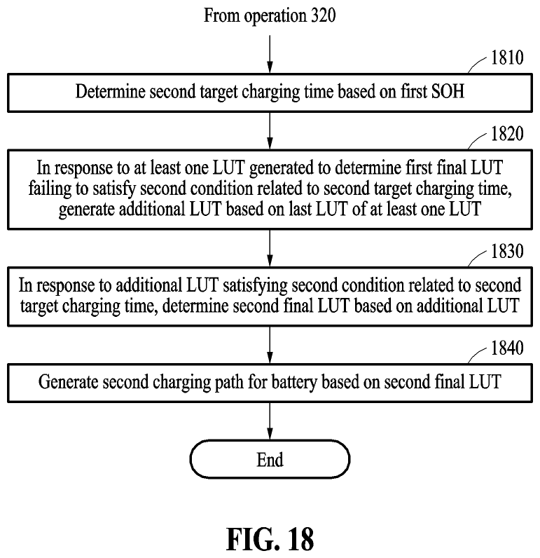

FIG. 18 illustrates an example method of determining a second target charging time according to one or more embodiments.

Referring to FIG. 18, in a non-limiting example, after operation 320, as described above with reference to FIG. 3, is performed, operations 1810 to 1840 may be performed. Operations 1810 to 1840 may be performed by an electronic device (e.g., the electronic device 200 of FIG. 2).

In operation 1810, the electronic device may determine a second target charging time based on a first SOH.

In an example, the electronic device may determine the second target charging time for a target charging interval based on a second coefficient, a total reference charging time, the first SOH, and a sub-charging time for the target charging interval. In an example, the target charging interval may be an entirety of a fast charging interval.

In an example, the second target charging time may be calculated based on Equation 7 shown below.

$${T}_{ch \_ target} = {T}_{ch \_ target \_ 0} - {α}_{2} \times {T}_{ch \_ full \_ 0} \times ( 1 - SOH ) \qquad Equation 7$$

In Equation 7, α₂ may be the second coefficient and may be different from the first coefficient. The description of operation 340 provided above with reference to FIG. 3 may similarly apply to the description of the example of determining the second target charging time.

In an example, the second target charging time may be longer than the first target charging time. In an example, the first charging path may be used to charge the battery when a circumstance in which the battery is charged is a preset first circumstance and the second charging path may be used to charge the battery when the circumstance in which the battery is charged is a preset second circumstance.

In an example, the second circumstance may be a circumstance in which the user does not mind that the battery may be charged for a long time. In an example, the second circumstance may include a circumstance in which the electronic device charging the battery operates in a sleep mode. The electronic device may operate in the sleep mode during a preset time according to the user setting and may charge the battery with the second charging path when charging in the sleep mode.

In operation 1820, when at least one LUT (e.g., LUT1 to LUT64 of FIG. 14) generated to determine a first final LUT (e.g., LUT63 or LUT64 of FIG. 14) fails to satisfy a second condition related to the second target charging time, an additional LUT may be generated based on a last LUT (e.g., LUT64 of FIG. 14) of the at least one LUT. The description of operation 370, as described in greater detail above with reference to FIG. 3, may similarly apply to the description of the example of generating the additional LUT.

In operation 1830, when the additional LUT satisfies the second condition related to the second target charging time, the electronic device may determine a second final LUT based on the additional LUT. The description of operation 380, as described in greater detail above with reference to FIG. 13, may similarly apply to the description of the example of determining the second final LUT.

In operation 1840, the electronic device may generate the second charging path for the battery based on the second final LUT. The description of operation 390, as described in greater detail above with reference to FIG. 3, may similarly apply to the description of the example of generating the second charging path.

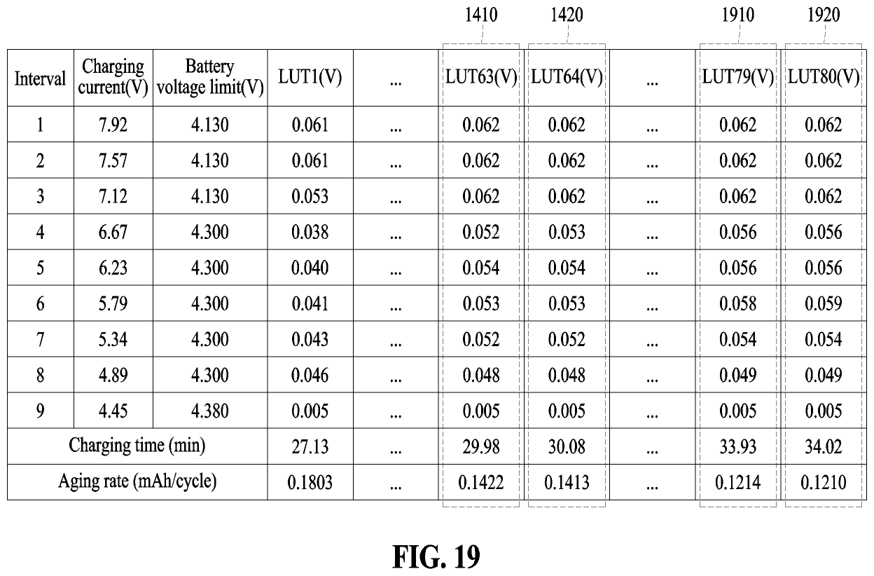

FIG. 19 illustrates an example initial LUT and a plurality of LUTs for generating a second charging path according to one or more embodiments.

Referring to FIG. 19, in a non-limiting example, when the initial LUT (e.g., LUT1) and the plurality of LUTs (e.g., LUT2 to LUT64) as described above with reference, for example, to FIG. 14 fail to satisfy the second condition related to the second target charging time, the electronic device may generate an additional LUT (e.g., LUT65) based on the last LUT (e.g., LUT64) of the plurality of LUTs.

When the additional LUT satisfies the second condition related to the second target charging time, the electronic device may determine the second final LUT based on the additional LUT. When the additional LUT fails to satisfy the second condition related to the second target charging time, the electronic device may determine yet another, additional LUT based on the additional LUT.

In an example, when the first target charging time is set to be 34 minutes, it may be determined that a result of LUT80 1920 satisfies the preset second condition. In an example, one of the plurality of LUTs may be determined to be the second final LUT according to a preset policy.

In an example, LUT80 1920 may be determined to be the second final LUT.

In an example, LUT79 1910, which is an LUT previous to LUT80 1920, may be determine to be the second final LUT.

In an example, since a difference for LUT80 1920 is calculated to be 0.02 minutes and a difference for LUT79 1910, which is the LUT previous to LUT80 1920, is calculated to be 0.07 minutes, LUT80 1920 may be determined to the second final LUT.

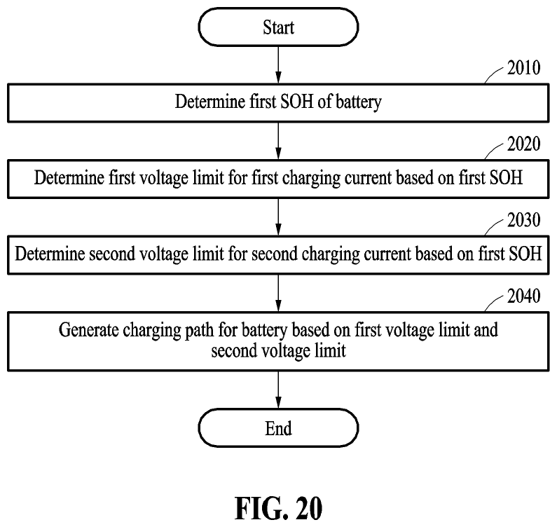

FIG. 20 illustrates an example method of generating a charging path for a battery based on a first voltage limit of a first charging current determined based on a first SOH of the battery and a second voltage limit of a second charging current according to one or more embodiments.

Referring to FIG. 20, in a non-limiting example, operations 2010 to 2040 may be performed by the electronic device (e.g., the electronic device 200 of FIG. 2) described above with reference to FIG. 2.

In operation 2010, the electronic device may determine a first SOH of the battery. Various schemes may be employed to determine or estimate an SOH. In an example, the electronic device may determine the first SOH of the battery using at least one parameter indicating the state of the battery or a battery model. In an example, the electronic device may calculate a first internal resistance of the battery and may determine the first SOH of the battery based on the calculated first internal resistance. The method of determining the first SOH of the battery is not limited to the examples described above.

In operation 2020, the electronic device may determine a first voltage limit for a first charging current based on the first SOH.

In an example, a fast charging interval of the total charging intervals of the battery may be divided into intervals charged using a plurality of charging currents. In an example, an interval in which 7.92 A is used may be defined as a first interval, an interval in which 7.57 A is used may be defined as a second interval, an interval in which 7.12 A is used may be defined as a third interval, an interval in which 6.67 A is used may be defined as a fourth interval, an interval in which 6.23 A is used may be defined as a fifth interval, an interval in which 5.79 A is used may be defined as a sixth interval, an interval in which 5.34 A is used may be defined as a seventh interval, an interval in which 4.89 A is used may be defined as an eighth interval, and an interval in which 4.45 A is used may be defined as a ninth interval. In an example, the voltage limit of the first interval for 7.92 A may be determined to be the first voltage limit.

In an example, the first voltage limit for the first charging current according to a change in the SOH of the battery may be stored in the electronic device in advance in the form of a table. The electronic device may obtain the first voltage limit for the first charging current corresponding to the first SOH.

In an example, the first voltage limit for the first changing current according to the change in the SOH of the battery may be stored in a server in advance in the form of a table. The server may store voltage limit information about various batteries. The electronic device may connect to the server, may transmit information about the battery and the first SOH to the server, and may receive a second voltage limit for the first charging current as a response from the server.

In operation 2030, the electronic device may determine the second voltage limit for a second charging current based on the first SOH. In an example, the voltage limit of the second interval for 7.57 A may be determined to be the second voltage limit. The description of the example of determining the first voltage limit may similarly apply to the description of the example of determining the second voltage limit.

In operation 2040, the electronic device may generate a charging path for the battery based on the first voltage limit and the second voltage limit.

In an example, while the electronic device charges the battery based on the charging path, when the voltage of the first interval charging using the first charging current reaches the first voltage limit, the electronic device may charge the second interval using the second charging current. The electronic device may stop fast charging when a voltage of an n-th interval charging using an n-th charging current, which is the last one, reaches an n-th voltage limit.

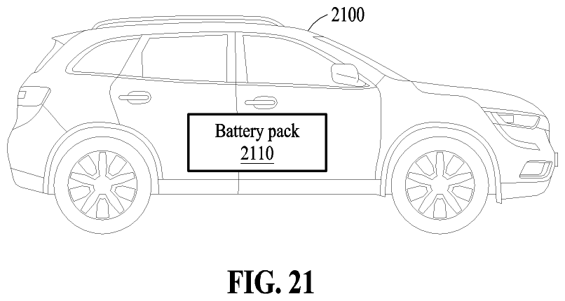

FIG. 21 illustrates an example vehicle according to one or more embodiments.

Referring to FIG. 21, in a non-limiting example, a vehicle 2100 may include a battery pack 2110. The vehicle 2100 may be a vehicle using the battery pack 2110 as a power source. The vehicle 2100 may be, for example, an electric vehicle or a hybrid vehicle.

The battery pack 2110 may include a battery management system (BMS) and battery cells (or battery modules). The BMS may monitor whether the battery pack 2110 shows an abnormality, and may prevent over-charging or over-discharging of the battery pack 2110. In addition, the BMS may perform thermal control for the battery pack 2110 when the temperature of the battery pack 2110 exceeds a first temperature (for example, 40° C.) or is less than a second temperature (for example, −10° C.). In addition, the BMS may perform cell balancing so that the battery cells in the battery pack 2110 have balanced charging states.

In an example, the vehicle 2100 may include a battery charging apparatus. The battery charging apparatus may generate a charging path of the battery pack 2110 (or the battery cells in the battery pack 2110), and charge the battery pack 2110 (or the battery cells in the battery pack 2110) using the generated charging path.

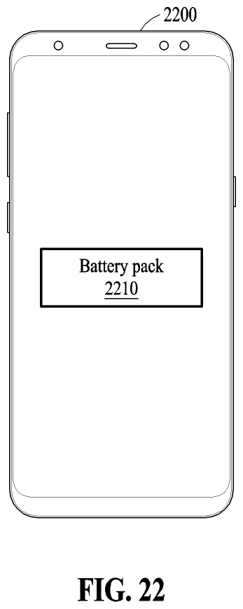

FIG. 22 illustrates an example mobile terminal according to one or more embodiments.

Referring to FIG. 22, in a non-limiting example, a mobile terminal 2200 may include a battery pack 2210. The mobile terminal 2200 may be a device using the battery pack 2210 as a power source. The mobile terminal 2200 may be a portable terminal, for example, a smartphone. The battery pack 2210 includes a BMS and battery cells (or battery modules).

In an example, the mobile terminal 2200 may include a battery charging apparatus. The battery charging apparatus may generate a charging path of the battery pack 2210 (or the battery cells in the battery pack 2210), and charge the battery pack 2210 (or the battery cells in the battery pack 2210) using the generated charging path.

FIG. 23 illustrates an example electronic device according to one or more embodiments.

Referring to FIG. 23, in a non-limiting example, an electronic device 2310 (e.g., the electronic device 200 of FIG. 2) may include a battery 2311 and a battery charging apparatus 2312. The electronic device 2310 may be a mobile terminal, such as a smartphone, a laptop, a tablet PC, or a wearable device, but is not limited thereto. The battery charging apparatus 2312 may be in the form of an integrated circuit (IC), but is not limited thereto. The battery charging apparatus 2312 may receive power from a power source 2320 in a wired or wireless manner and may charge the battery 2311 using the power. The battery charging apparatus 2312 may generate a charging path for the battery 2311 and may charge the battery charging apparatus 2311 using the charging path.

The batteries, memories, processors, charging apparatuses, electronic apparatuses, electronic device 200, communicator 210, processor 220, memory 230, vehicle 2100, battery pack 2110, mobile terminal, battery pack 2210, electronic device 2310, battery 2311, power source 2320, and battery charging apparatus 2312 described herein and disclosed herein described with respect to FIGS. 1-23 are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-23 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as multimedia card micro or a card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A method, the method comprising:
determining a first target charging time based on a first state of health (SOH) of a battery;
generating simulation data for preset charging currents based on a battery model indicating an internal state of the battery;
generating an initial look-up table (LUT) for the preset charging currents and preset battery voltage limits based on the simulation data, wherein the initial LUT represents initial charging limit conditions of the battery for intervals respectively corresponding to the charging currents;
generating one or more modified LUTs by adjusting one or more of the initial charging limit conditions of the initial LUT, responsive to the initial LUT failing to satisfy a first condition related to the first target charging time;
determining a first final LUT based on a final LUT of the one or more modified LUTs, responsive to the final LUT satisfying the first condition related to the first target charging time; and
generating a first charging path for the battery based on the first final LUT.

2. The method of claim 1, further comprising:
determining the first SOH of the battery using a battery model.

3. The method of claim 1, wherein the determining of the first target charging time based on the first SOH comprises:
determining a first target charging time for a target charging interval, based on a first coefficient, a total reference charging time, the first SOH, and a reference sub-charging time for the target charging interval.

4. The method of claim 1, further comprising:
determining a second target charging time based on the first SOH;
in response to the first final LUT failing to satisfy a second condition related to the second target charging time, generating an additional LUT based on the final LUT;
in response to the additional LUT satisfying the second condition related to the second target charging time, determining a second final LUT based on the additional LUT; and
generating a second charging path for the battery based on the second final LUT.

5. The method of claim 4, wherein the second target charging time is longer than the first target charging time.

6. The method of claim 4, wherein the first charging path is employed for charging the battery responsive to preset first circumstance, and
the second charging path is employed for charging the battery responsive to a preset second circumstance.

7. The method of claim 6, wherein the preset second circumstance comprises a circumstance in which an electronic device charging the battery operates in a sleep mode.

8. The method of claim 1, further comprising:
obtaining one or more parameters indicating a state of the battery; and
updating the battery model based on the one or more parameters,
wherein the generating of the simulation data comprises generating the simulation data for the preset charging currents based on the updated battery model.

9. The method of claim 1, wherein the generating of the initial LUT comprises:
determining, to be a first initial charging limit condition for a first interval, a first anode potential at a first point in time at which a first charging current of the preset charging currents reaches a first battery voltage limit of the preset battery voltage limits;
determining, to be a second initial charging limit condition for a second interval, a second anode potential at a second point in time at which a second charging current of the preset charging currents reaches a second battery voltage limit of the preset battery voltage limits; and
generating the initial LUT based on the first initial charging limit condition and the second initial charging limit condition.

10. The method of claim 9, wherein the determining of whether the initial LUT satisfies the first condition comprises:
generating a first charging result for the first interval and a second charging result for the second interval;
generating a charging result for the initial LUT based on the first charging result and the second charging result; and
determining whether the charging result satisfies the first condition.

11. The method of claim 1, further comprising generating the final LUT, the generating comprising:
generating a plurality of candidate LUTs by adjusting each of the initial charging limit conditions of the initial LUT within a preset range;
calculating efficiencies for the plurality of candidate LUTs;
determining a target stage showing a highest efficiency from among the intervals of the initial LUT based on the efficiencies; and
generating the final LUT by adjusting a value of a target initial charging limit condition of intervals of the initial LUT.

12. The method of claim 11, wherein the calculating of the efficiencies for the plurality of candidate LUTs comprises:
calculating a first charging time and a first aging rate of a first candidate LUT; and
calculating a first efficiency for the first candidate LUT based on the first charging time and the first aging rate.

13. The method of claim 12, wherein the calculating of the first charging time and the first aging rate of the first candidate LUT comprises:
calculating a first sub-charging time and a first sub-aging rate for a first interval of the first candidate LUT;
calculating a second sub-charging time and a second sub-aging rate for a second interval of the first candidate LUT; and
calculating the first charging time based on the first sub-charging time and the second sub-charging time and calculating the first aging rate based on the first sub-aging rate and the second sub-aging rate.

14. The method of claim 1, wherein the determining of the first final LUT comprises:
calculating a first difference between a charging time of the final LUT and the first target charging time;
calculating a second difference between a charging time of an LUT previous to the final LUT of the one or more modified LUTs and the first target charging time; and
determining an LUT from among the one or more modified LUTs having a smaller one of the first difference and the second difference to be the first final LUT.

15. The method of claim 1, wherein the battery is comprised in a mobile terminal or a vehicle.

16. An electronic device comprising:
processors configured to execute instructions; and
a memory storing the instructions, wherein execution of the instructions configures the processors to:
determine a first target charging time based on a first state of health (SOH) of a battery;
generate simulation data for preset charging currents based on a battery model indicating an internal state of the battery;
generate an initial look-up table (LUT) for the charging currents and preset battery voltage limits based on the simulation data, wherein the initial LUT represents initial charging limit conditions of the battery for intervals corresponding to the charging currents;
generate a modified LUT by adjusting one or more of the initial charging limit conditions of the initial LUT, in response to the initial LUT failing to satisfy a first condition related to the first target charging time;
determine a first final LUT based on the modified LUT, in response to the modified LUT satisfying the first condition related to the first target charging time; and
generate a first charging path for the battery based on the first final LUT.

17. A method of generating a charging path for a battery, the method comprising:
determining a first state of health (SOH) of a battery;
determining a first voltage limit for a first charging current based on the first SOH;
determining a second voltage limit for a second charging current based on the first SOH; and
generating a charging path for the battery based on the first voltage limit and the second voltage limit.

18. The method of claim 17, wherein the determining of the first SOH of the battery comprises:
determining a first internal resistance of the battery; and
determining the first SOH based on the first internal resistance.

19. The method of claim 17, wherein the generating of the charging path for the battery further comprises:
determining a first target charging time based on the first SOH of the battery; and determining a second target charging time based on the first SOH, wherein the second target charging time is longer than the first target charging time.

20. The method of claim 17, wherein the generating of the charging path for the battery further comprises:
generating a first final LUT by iteratively adjusting one or more of initial charging limit conditions until one or more LUTs satisfy a first condition related to a first target charging time based on the first SOH of the battery, and
wherein the generating of the first charging path for the battery is based on the first final LUT.
